(19) United States
(12) Patent Application Publication
(10) Pub. No.: US 2026/0358691 A1
(43) Pub. Date: Nov. 12, 2026

(54) REFLECTIVE MASK BLANK, REFLECTIVE MASK, AND METHOD FOR MANUFACTURING REFLECTIVE MASK AND SEMICONDUCTOR DEVICE

(71) Applicant: HOYA CORPORATION, Tokyo (JP)

(72) Inventors: Hibiki KISHIDA, Tokyo (JP); Masanori NAKAGAWA, Tokyo (JP)

(73) Assignee: HOYA CORPORATION, Tokyo (JP)

(21) Appl. No.: 19/120,863

(22) PCT Filed: Oct. 10, 2023
(86) PCT No.: PCT/JP2023/036797

§ 371 Date: Apr. 14, 2025

(30) Foreign Application Priority Data
Oct. 21, 2022 (JP) 2022-169332

(51) Int. Cl. G03F 1/24; C23C 14/06; C23C 14/08; C23C 14/18; C23C 14/34; C23C 14/35; C23C 14/46; G03F 7/00; H10P 76/00

(52) U.S. Cl. CPC G03F 1/24; C23C 14/0641; C23C 14/067; C23C 14/0676; C23C 14/083; C23C 14/18; C23C 14/3464; C23C 14/35; C23C 14/46; G03F 7/0005; H10P 76/00

(57) ABSTRACT

Provided is a reflective mask blank capable of reducing diffusion of boron (B) comprised in an absorber film into an etching mask film.

A reflective mask blank comprises: a substrate; a multilayer reflective film; an absorber film comprising a first absorption layer and a second absorption layer; and an etching mask film, in which the first absorption layer comprises boron (B), a content ratio of boron (B) in the second absorption layer is smaller than a content ratio of boron (B) in the first absorption layer, the etching mask film comprises a metal (M), and in content ratio profiles of boron (B) and the metal (M) with respect to a sputtering time, obtained by sputtering at least a part of the etching mask film, the second absorption layer, and the first absorption layer in a film thickness direction, the content ratio profile of boron (B) satisfies a predetermined relationship.

### TECHNICAL FIELD

The present invention relates to a reflective mask used for manufacturing a semiconductor device and the like, a method for manufacturing the reflective mask, and a reflective mask blank used for manufacturing the reflective mask. The present invention also relates to a method for manufacturing a semiconductor device using the above reflective mask.

### BACKGROUND ART

With a further demand for higher density and higher accuracy of a VLSI device in recent years, extreme ultraviolet (hereinafter, referred to as “EUV”) lithography, which is an exposure technique using EUV light, has been proposed.

A reflective mask includes a multilayer reflective film for reflecting exposure light formed on a substrate, and an absorber pattern which is a patterned absorber film formed on the multilayer reflective film for absorbing exposure light. In EUV lithography using the reflective mask, a light image reflected by the multilayer reflective film of the reflective mask is transferred onto a semiconductor substrate (transferred object) such as a silicon wafer through a reflective optical system. A reflective mask blank is used to manufacture the reflective mask.

Patent Documents 1 to 3 describe examples of the reflective mask blank.

Patent Document 1 describes a mask blank including, on a substrate, a reflection layer that reflects exposure light in a short wavelength region including an extreme ultraviolet region and an absorber layer that absorbs the exposure light in order. Specifically, Patent Document 1 describes that the absorber layer has at least a two-layer structure in which an absorber layer including an absorber of exposure light in a short wavelength region including an extreme ultraviolet region is a lower layer, and a low reflection layer including an absorber of inspection light used for inspecting a mask pattern is an upper layer, that the upper layer is made of a material containing tantalum (Ta), boron (B), and nitrogen (N), and that regarding a composition among Ta, B, and N, a content ratio of B is 5 at % to 30 at % and a composition ratio between Ta and N (Ta:N) is within a range of 8:1 to 2:7.

Patent Document 2 describes a reflective mask blank for exposure, including: a substrate; and a multilayer reflective film that reflects exposure light and an absorber film absorbs exposure light, sequentially formed on the substrate. Patent Document 2 also describes that an intermediate layer having resistance to an etching environment of the absorption film is formed between the multilayer reflective film and the absorption film, and that the intermediate layer is made of a material containing Ta as a main metal component.

Patent Document 3 describes a reflective mask blank used for preparing a reflective mask. Patent Document 3 describes that the reflective mask blank has a structure in which a reflective film, an absorber film, and an etching mask film are layered in this order. Patent Document 3 also describes that the etching mask film is made of a material containing chromium, that the absorber film is made of a material containing tantalum, that a high oxide layer is formed on a surface layer of the absorber film opposite to a substrate side, and that in the high oxide layer, a narrow spectrum of Ta4f when performing X-ray electron spectroscopic analysis has a maximum peak with bound energy larger than 23 eV.

### PRIOR ART DOCUMENTS

### Patent Documents

Patent Document 1: JP 2004-6798 A
Patent Document 2: JP 2003-318101 A
Patent Document 3: JP 2013-84910 A

### DISCLOSURE OF INVENTION

The above-described EUV lithography is an exposure technique using extreme ultraviolet light (EUV light). The EUV light refers to light in a wavelength band of a soft X-ray region or a vacuum ultraviolet region, and is specifically light having a wavelength of about 0.2 to 100 nm. In the EUV lithography, EUV light having a wavelength of 13 to 14 nm (for example, a wavelength of 13.5 nm) can be used.

In the EUV lithography, a reflective mask having an absorber pattern is used. EUV light with which the reflective mask is irradiated is absorbed in a portion where the absorber pattern is present, and is reflected in a portion where the absorber pattern is not present. A multilayer reflective film is exposed in the portion where the absorber pattern is not present. The multilayer reflective film exposed on a surface of the reflective mask reflects the EUV light. In the EUV lithography, a light image reflected by the multilayer reflective film (a portion where the absorber pattern is not present) is transferred onto a semiconductor substrate (transferred object) such as a silicon wafer through a reflective optical system.

As the multilayer reflective film, a multilayer film in which elements having different refractive indices are periodically layered is used. For example, as a multilayer reflective film with respect to EUV light having a wavelength of 13 to 14 nm (for example, a wavelength of 13.5 nm), a Mo/Si periodic layered film in which a Mo film having a low refractive index and a Si film having a high refractive index are alternately layered for 40 to 60 periods is used.

In order to achieve high density and/or high accuracy of a semiconductor device using the reflective mask, a reflection region (surface of the multilayer reflective film) in the reflective mask needs to have a high reflectance with respect to EUV light that is exposure light.

In a process of manufacturing a reflective mask, when an absorber pattern is formed, an absorber film of a reflective mask blank needs to be processed by etching. In order to process the absorber film into an absorber pattern having a designed shape, an etching mask film can be used. Specifically, an etching mask pattern obtained by patterning the etching mask film is formed on the absorber film, and the absorber film is etched via the etching mask pattern, whereby a predetermined absorber pattern can be formed. The etching mask film needs to have high resistance to an etching gas used for etching the absorber film.

In the process of manufacturing a reflective mask, after an absorber film is etched via an etching mask pattern to form an absorber pattern, it is necessary to remove an unnecessary etching mask pattern by etching. In a portion where an absorber pattern is not formed, a multilayer reflective film or a protective film formed on the multilayer reflective film is exposed. A predetermined time is required to etch and remove the etching mask pattern. When the predetermined time is too long, the multilayer reflective film and/or the protective film may be damaged. When the multilayer reflective film and/or the protective film is damaged, a reflectance of the multilayer reflective film with respect to EUV light decreases, and there arises a problem that performance of the reflective mask is deteriorated.

On the other hand, by making a crystal structure of the absorber film amorphous, surface roughness of a surface of the absorber film can be reduced. In order to make the crystal structure of the absorber film amorphous, boron (B) can be added to a material of the absorber film. However, it has been found that boron (B) contained in the absorber film may diffuse into an etching mask film formed in contact with the surface of the absorber film. The present inventors have found that by inclusion of boron (B) in the etching mask film, a phenomenon that an etching rate of the etching mask film decreases occurs. When the etching rate of the etching mask film decreases, the time for etching and removing the etching mask pattern becomes long as described above in the process of manufacturing a reflective mask. This causes a problem that the multilayer reflective film and/or the protective film is damaged when the etching mask pattern is removed by etching. As a result, a reflectance of the multilayer reflective film with respect to EUV light decreases, and there arises a problem that performance of the reflective mask is deteriorated.

Therefore, an object of the present invention is to provide a reflective mask blank capable of reducing diffusion of boron (B) contained in an absorber film into an etching mask film. Another object of the present invention is to provide a method for manufacturing a reflective mask capable of reducing damage to a multilayer reflective film and/or a protective film when an etching mask pattern is removed by etching.

Another object of the present invention is to provide a reflective mask capable of reducing damage to a multilayer reflective film and/or a protective film, and to provide a method for manufacturing a semiconductor device using the reflective mask.

In order to solve the above problems, the present invention has the following configurations.

### (Configuration 1)

Configuration 1 is a reflective mask blank comprising:
a substrate;
a multilayer reflective film disposed on the substrate;
an absorber film disposed on the multilayer reflective film and comprising a first absorption layer and a second absorption layer; and
an etching mask film disposed in contact with the second absorption layer, in which
the first absorption layer comprises boron (B),
a content ratio of boron (B) in the second absorption layer is smaller than a content ratio of boron (B) in the first absorption layer,
the etching mask film comprises a metal (M), and
in content ratio profiles of boron (B) and the metal (M) with respect to a sputtering time, obtained by sputtering at least a part of the etching mask film, the second absorption layer, and the first absorption layer in a film thickness direction,
the content ratio profile of boron (B) satisfies the following formula (1),

$$\begin{matrix}[ Mathematical Formula 1 ] & \\ {\int }_{- ∞}^{{u}_{M}} {S}_{B} ( t ) dt ≦ 2. ( atomic \% \cdot minute ) & ( 1 )\end{matrix}$$

in which t represents a sputtering time,
S_{B}(t) represents an arbitrary S-shaped function approximating the content ratio profile of boron (B), and
u_{M} represents an inflection point when the content ratio profile of the metal (M) is approximated by the arbitrary S-shaped function.

### (Configuration 2)

Configuration 2 is the reflective mask blank according to configuration 1, in which the second absorption layer has a film thickness of 0.5 nm or more and 20 nm or less.

### (Configuration 3)

Configuration 3 is the reflective mask blank according to configuration 1 or 2, in which the second absorption layer comprises at least one selected from tantalum (Ta), chromium (Cr), platinum (Pt), ruthenium (Ru), and gold (Au).

### (Configuration 4)

Configuration 4 is the reflective mask blank according to any one of configurations 1 to 3, in which the first absorption layer comprises at least one selected from tantalum (Ta), chromium (Cr), platinum (Pt), ruthenium (Ru), and gold (Au).

### (Configuration 5)

Configuration 5 is the reflective mask blank according to any one of configurations 1 to 4, in which the first absorption layer and the second absorption layer each comprise tantalum (Ta).

### (Configuration 6)

Configuration 6 is the reflective mask blank according to any one of configurations 1 to 5, in which the metal (M) of the etching mask film comprises chromium (Cr).

### (Configuration 7)

Configuration 7 is the reflective mask blank according to any one of configurations 1 to 6, further comprising a protective film comprising at least one selected from ruthenium (Ru) and rhodium (Rh) between the multilayer reflective film and the absorber film.

### (Configuration 8)

Configuration 8 is a reflective mask further comprising an absorber pattern obtained by patterning the absorber film disposed on the multilayer reflective film or the protective film of the reflective mask blank according to any one of configurations 1 to 7.

### (Configuration 9)

Configuration 9 is a method for manufacturing a reflective mask, comprising:
preparing the reflective mask blank according to any one of configurations 1 to 7; and
patterning the absorber film to form an absorber pattern.

### (Configuration 10)

Configuration 10 is a method for manufacturing a semiconductor device, comprising performing a lithography process with an exposure apparatus using the reflective mask according to configuration 8 to form a transfer pattern on a transferred object.

According to the present invention, it is possible to provide a reflective mask blank capable of reducing diffusion of boron (B) contained in an absorber film into an etching mask film. In addition, according to the present invention, it is possible to provide a method for manufacturing a reflective mask capable of reducing damage to a multilayer reflective film and/or a protective film when an etching mask pattern is removed by etching.

In addition, according to the present invention, it is possible to provide a reflective mask capable of reducing damage to a multilayer reflective film and/or a protective film, and to provide a method for manufacturing a semiconductor device using the reflective mask.

### BRIEF DESCRIPTION OF DRAWINGS

FIG. 1 is a schematic cross-sectional view illustrating an example of a reflective mask blank of the present embodiment.

FIG. 2 is a schematic cross-sectional view illustrating another example of the reflective mask blank of the present embodiment.

FIGS. 3A to 3E are schematic cross-sectional views illustrating an example of a method for manufacturing a reflective mask of the present embodiment.

FIG. 4 is a schematic diagram illustrating an example of an EUV exposure apparatus.

FIG. 5 is a diagram for explaining a content ratio profile of a metal (M) and a content ratio profile of boron (B) obtained by sputtering an absorber film and an etching mask film in a film thickness direction in a reflective mask blank.

### DESCRIPTION OF EMBODIMENTS

Hereinafter, an embodiment of the present invention will be specifically described with reference to the drawings. Note that the following embodiment is a mode for specifically describing the present invention and does not limit the present invention within the scope thereof.

### <Reflective Mask Blank 100>

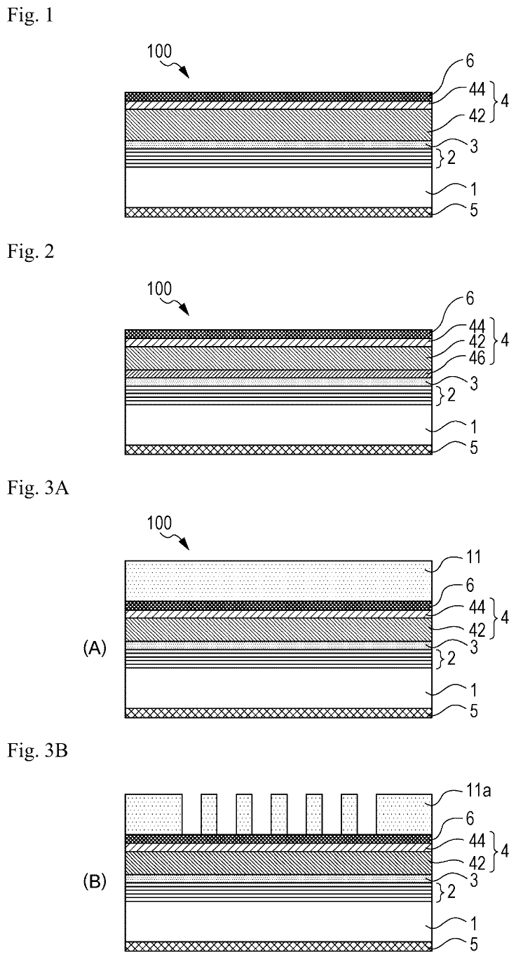

FIG. 1 is a schematic cross-sectional view illustrating an example of a reflective mask blank 100 of the present embodiment. The reflective mask blank 100 illustrated in FIG. 1 includes a multilayer reflective film 2 disposed on a substrate 1, an absorber film 4 disposed on the multilayer reflective film 2 and including a first absorption layer 42 and a second absorption layer 44, and an etching mask film 6 disposed in contact with the second absorption layer 44. The first absorption layer 42 is disposed between the second absorption layer 44 and the multilayer reflective film 2. As illustrated in FIG. 1, the reflective mask blank 100 of the present embodiment can further include a protective film 3 between the multilayer reflective film 2 and the absorber film 4.

The absorber film 4 of the reflective mask blank 100 of the present embodiment can include a thin film other than the first absorption layer 42 and the second absorption layer 44. As illustrated in FIG. 2, the absorber film 4 of the reflective mask blank 100 can further include a buffer layer 46 on the multilayer reflective film 2 in contact with the protective film 3.

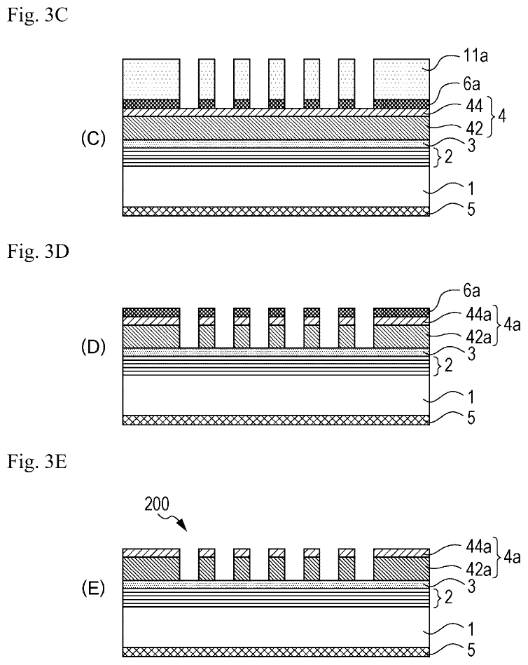

The reflective mask blank 100 illustrated in FIGS. 1 and 2 can further include another thin film such as a conductive back film 5. As illustrated in FIG. 3A, the reflective mask blank 100 of the present embodiment can further include a resist film 11.

In the present specification, “a thin film B is disposed (formed) on a thin film A (or substrate)” includes not only a case where the thin film B is disposed (formed) in contact with a surface of the thin film A (or substrate) but also a case where there is another thin film C between the thin film A (or substrate) and the thin film B. In addition, in the present specification, for example, “a thin film B is disposed in contact with a surface of a thin film A (or substrate)” means that the thin film A (or substrate) and the thin film B are disposed in direct contact with each other without another thin film interposed between the thin film A (or substrate) and the thin film B. In addition, in the present specification, “on” does not necessarily mean an upper side in the vertical direction. “On” merely indicates a relative positional relationship among a thin film, a substrate, and the like.

The reflective mask blank 100 of the present embodiment will be specifically described.

### <<Substrate 1>>

As the substrate 1, a substrate having a low thermal expansion coefficient within a range of 0±5 ppb/°C is preferably used in order to prevent distortion of a transfer pattern due to heat during exposure to EUV light. As a material having a low thermal expansion coefficient within this range, for example, SiO₂—TiO₂-based glass, multicomponent-based glass ceramic, or the like can be used.

A main surface (first main surface) of the substrate 1 on a side where a transfer pattern (absorber pattern 4a described later) is formed is preferably processed in order to increase a flatness. By increasing the flatness of the main surface of the substrate 1, position accuracy and transfer accuracy of the pattern can be increased. For example, in a case of EUV exposure, the flatness in a region of 132 mm×132 mm of the main surface of the substrate 1 on the side where the transfer pattern is formed is preferably 0.1 μm or less, more preferably 0.05 μm or less, and particularly preferably 0.03 μm or less. In addition, a second main surface (back surface) opposite to the side where the transfer pattern is formed is a surface to be fixed to an exposure apparatus by an electrostatic chuck. The flatness in a region of 142 mm×142 mm of the back surface is preferably 0.1 μm or less, more preferably 0.05 μm or less, and particularly preferably 0.03 μm or less. Note that, in the present specification, the flatness is a value representing warpage (deformation amount) of a surface indicated by total indicated reading (TIR). The flatness (TIR) is an absolute value of a difference in height between the highest position of a surface of the substrate 1 above a focal plane and the lowest position of the surface of the substrate 1 below the focal plane, in which the focal plane is a plane defined by a minimum square method using the surface of the substrate 1 as a reference.

In a case of EUV exposure, the main surface of the substrate 1 on a side where the transfer pattern is formed preferably has a surface roughness of 0.1 nm or less in terms of root mean square roughness (Rq). Note that the surface roughness can be measured with an atomic force microscope.

The substrate 1 preferably has a high rigidity in order to prevent deformation of a thin film (such as the multilayer reflective film 2) formed on the substrate 1 due to a film stress. In particular, the substrate 1 preferably has a high Young's modulus of 65 GPa or more.

### <<Multilayer Reflective Film 2>>

The reflective mask blank 100 of the present embodiment includes the multilayer reflective film 2. The multilayer reflective film 2 provides a reflective mask 200 with a function that reflects EUV light. The multilayer reflective film 2 is a multilayer film in which layers mainly containing elements having different refractive indices are periodically layered.

In general, as the multilayer reflective film 2, a multilayer film in which a thin film (high refractive index layer) of a light element that is a high refractive index material or a compound of the light element and a thin film (low refractive index layer) of a heavy element that is a low refractive index material or a compound of the heavy element are alternately layered for about 40 to 60 periods.

When a stack of high refractive index layer/low refractive index layer in which the high refractive index layer and the low refractive index layer are layered in this order from the substrate 1 side is counted as one period, the multilayer film used as the multilayer reflective film 2 can be formed by building up the stack for a plurality of periods. In addition, when a stack of low refractive index layer/high refractive index layer in which the low refractive index layer and the high refractive index layer are layered in this order from the substrate 1 side is counted as one period, the multilayer film can be formed by building up the stack for a plurality of periods. Note that an outermost layer of the multilayer reflective film 2, that is, a surface layer of the multilayer reflective film 2 opposite to the substrate 1 side is preferably the high refractive index layer. In the above-described multilayer film, when a stack of high refractive index layer/low refractive index layer in which the high refractive index layer and the low refractive index layer are layered in this order from the substrate 1 side is counted as one period and the stack is built up for a plurality of periods, the uppermost layer is the low refractive index layer. In this case, when the low refractive index layer constitutes the outermost surface of the multilayer reflective film 2, the low refractive index layer is easily oxidized and the reflectance of the reflective mask 200 is therefore reduced. Therefore, it is preferable to further form a high refractive index layer on the low refractive index layer that is the uppermost layer to form the multilayer reflective film 2. Meanwhile, in the above-described multilayer film, when a stack of low refractive index layer/high refractive index layer in which the low refractive index layer and the high refractive index layer are layered in this order from the substrate 1 side is counted as one period and the stack is built up for a plurality of periods, the uppermost layer is the high refractive index layer. Therefore, in this case, it is not necessary to further form the high refractive index layer.

As the high refractive index layer, a layer containing silicon (Si) can be used. As a material containing Si, a Si compound containing Si and boron (B), carbon (C), nitrogen (N), oxygen (O), and/or hydrogen (H) can be used in addition to a Si simple substance. By using the high refractive index layer containing Si, the reflective mask 200 having an excellent reflectance with respect to EUV light can be obtained. In addition, as the low refractive index layer, a metal simple substance selected from molybdenum (Mo), ruthenium (Ru), rhodium (Rh), and platinum (Pt), or an alloy thereof can be used. In addition, to these metal simple substances or alloys, boron (B), carbon (C), nitrogen (N), oxygen (O), and/or hydrogen (H) may be added. In the reflective mask blank 100 of the present embodiment, the low refractive index layer is preferably a molybdenum (Mo) layer, and the high refractive index layer is preferably a silicon (Si) layer. For example, as the multilayer reflective film 2 for reflecting EUV light having a wavelength of 13 nm to 14 nm (for example, a wavelength of 13.5 nm), a Mo/Si periodic layered film in which a Mo layer and a Si layer are alternately layered for about 40 to 60 periods can be preferably used. In addition, in the reflective mask blank 100 of the present embodiment, the low refractive index layer is preferably a ruthenium (Ru) layer, and the high refractive index layer is preferably a silicon (Si) layer. For example, as the multilayer reflective film 2 for reflecting EUV light having a wavelength of 13 nm to 14 nm (for example, a wavelength of 13.5 nm), a Ru/Si periodic layered film in which a Ru layer and a Si layer are alternately layered for about 30 to 40 periods can be preferably used.

A reflectance of the multilayer reflective film 2 alone is usually 65% or more, and an upper limit thereof is usually 73%. Note that the film thickness and period of each constituent layer of the multilayer reflective film 2 can be appropriately selected depending on an exposure wavelength. Specifically, the film thickness and period of each constituent layer of the multilayer reflective film 2 can be selected so as to satisfy Bragg's reflection law. In the multilayer reflective film 2, there are a plurality of high refractive index layers and a plurality of low refractive index layers, but the film thickness does not need to be the same between the high refractive index layers and between the low refractive index layers.

A method for forming the multilayer reflective film 2 is publicly known in this technical field. For example, the multilayer reflective film 2 can be formed by forming each layer by an ion beam sputtering method. In the case of the above-described Mo/Si periodic multilayer film, a Si film having a thickness of about 4 nm is first formed on the substrate 1 using a Si target, for example, by the ion beam sputtering method or a magnetron sputtering method. Then, a Mo film having a thickness of about 3 nm is formed using a Mo target. This stack is counted as one period and the Si film, and the Mo film are stacked for 40 to 60 periods to form the multilayer reflective film 2 (the outermost layer is the Si film). Note that, in the case of 60 periods, the number of steps is larger than the number of steps in the case of 40 periods, but the reflectance with respect to EUV light can be increased.

### <<Protective Film 3>>

The reflective mask blank 100 of the present embodiment preferably includes the protective film 3 between the multilayer reflective film 2 and the absorber film 4 described later. The protective film 3 is disposed in contact with a surface of the multilayer reflective film 2 opposite to the substrate 1.

In the reflective mask blank 100 of the present embodiment, the protective film 3 is formed between the multilayer reflective film 2 and the absorber film 4, and it is thereby possible to suppress damage to a surface of the multilayer reflective film 2 in manufacture of the reflective mask 200 (EUV mask) using the reflective mask blank 100. Therefore, a reflectance characteristic of the obtained reflective mask 200 with respect to EUV light is favorable.

The protective film 3 preferably contains at least one selected from ruthenium (Ru), rhodium (Rh), and iridium (Ir). The protective film 3 more preferably contains at least one selected from ruthenium (Ru) and rhodium (Rh). In addition, the protective film 3 can further contain an additive element in addition to the above-described elements. The additive element contained in the protective film 3 is preferably one or more elements selected from Tl, Hf, Ti, Zr, Mn, In, Ga, Cd, Bi, Ta, Pb, Ag, Al, V, Nb, Sn, Zn, Hg, Cr, Fe, Sb, W, Mo, and Cu.

A content ratio of Ru used for the protective film 3 is 50 atomic % or more and less than 100 atomic %, preferably 80 atomic % or more and less than 100 atomic %, and more preferably 95 atomic % or more and less than 100 atomic %. The content ratio of Rh is 10 atomic % or more and less than 70 atomic %, preferably 20 atomic % or more and less than 60 atomic %, and more preferably 30 atomic % or more and less than 50 atomic %. The protective film 3 in this case can have mask cleaning resistance, an etching stopper function when the absorber film 4 is etched, and a function of preventing the multilayer reflective film 2 from changing with time while sufficiently ensuring a reflectance with respect to EUV light.

The protective film 3 can have a stack of two or more layers.

In the reflective mask blank 100 of the present embodiment, an underlayer may be formed between the substrate 1 and the multilayer reflective film 2. The underlayer can be formed for the purpose of improving smoothness of the main surface of the substrate 1, reducing defects, enhancing a reflectance of the multilayer reflective film 2, and correcting a stress of the multilayer reflective film 2.

### <<Conductive Back Film 5>>

The reflective mask blank 100 of the present embodiment can include the conductive back film 5 for an electrostatic chuck. The conductive back film 5 can be formed on the second main surface (back surface) of the substrate 1 (on a surface opposite to a surface on which the multilayer reflective film 2 is formed or on an intermediate layer such as a hydrogen intrusion suppressing film when the intermediate layer is formed on the substrate 1). Sheet resistance required for the conductive back film 5 for an electrostatic chuck is usually 100Ω/□ (Ω/square) or less. A method for forming the conductive back film 5 is, for example, a magnetron sputtering method or an ion beam sputtering method using a target of a metal such as chromium or tantalum or an alloy thereof. A material containing chromium (Cr) for the conductive back film 5 is preferably a Cr compound containing Cr and at least one selected from boron, nitrogen, oxygen, and carbon. Examples of the Cr compound include CrN, CrON, CrCN, CrCON, CrBN, CrBON, CrBCN, CrBOCN, and the like. As a material containing tantalum (Ta) for the conductive back film 5, it is preferable to use Ta (tantalum), an alloy containing Ta, or a Ta compound containing either Ta or an alloy containing Ta and at least one selected from boron, nitrogen, oxygen, and carbon. Examples of the Ta compound include TaB, TaN, TaO, TaON, TaCON, TaBN, TaBO, TaBON, TaBCON, TaHf, TaHfO, TaHfN, TaHfON, TaHfCON, TaSi, TaSiO, TaSiN, TaSiON, TaSiCON, and the like. The film thickness of the conductive back film 5 is not particularly limited as long as a function of the conductive back film 5 for an electrostatic chuck is satisfied, but is usually 10 nm to 200 nm. The conductive back film 5 also adjusts a stress on the second main surface side of the mask blank 100. That is, the conductive back film 5 is adjusted such that the flat reflective mask blank 100 can be obtained in balance with a stress from various films formed on the first main surface side.

Note that the reflective mask blank 100 does not necessarily include the conductive back film 5. For example, the conductive back film 5 can be formed on the reflective mask blank 100 in which the absorber film 4 described later is formed as necessary.

### <<Absorber Film 4>>

As illustrated in FIGS. 1 and 2, the absorber film 4 of the reflective mask blank 100 of the present embodiment is disposed on the multilayer reflective film 2 described above. When the reflective mask blank 100 includes the protective film 3, the absorber film 4 is disposed on the protective film 3. The absorber film 4 can be disposed in contact with a surface of the protective film 3. When the reflective mask blank 100 does not include the protective film 3, the absorber film 4 can be disposed in contact with a surface of the multilayer reflective film 2.

A basic function of the absorber film 4 is to absorb EUV light. The absorber film 4 may be the absorber film 4 for the purpose of absorbing EUV light, or may be the absorber film 4 having a phase shift function in consideration of a phase difference of EUV light. The absorber film 4 having a phase shift function absorbs EUV light and reflects a part of the EUV light to shift a phase. That is, in the reflective mask 200 in which the absorber film 4 having a phase shift function is patterned, in a portion where the absorber film 4 is formed, a part of light is reflected at a level that does not adversely affect pattern transfer while EUV light is absorbed and attenuated. In addition, in a region (field portion) where the absorber film 4 is not formed, EUV light is reflected by the multilayer reflective film 2 (via the protective film 3 when there is the protective film 3). Therefore, there is a desired phase difference between reflected light from the absorber film 4 having a phase shift function and reflected light from the field portion. The absorber film 4 having a phase shift function is formed such that a phase difference between reflected light from the absorber film 4 and reflected light from the multilayer reflective film 2 is 170 to 260 degrees. Beams of the light having a reversed phase difference interfere with each other at a pattern edge portion, and an image contrast of a projected optical image is thereby improved. As the image contrast is improved, resolution is increased, and various exposure-related margins such as an exposure margin and a focus margin can be increased.

As illustrated in FIGS. 1 and 2, the absorber film 4 of the reflective mask blank 100 of the present embodiment includes the first absorption layer 42 and the second absorption layer 44. The first absorption layer 42 is disposed between the second absorption layer 44 and the multilayer reflective film 2 (or between the second absorption layer 44 and the protective film 3 when the protective film 3 is present). The absorber film 4 can include another film other than the first absorption layer 42 and the second absorption layer 44.

The first absorption layer 42 contains a metal (M_{A1}) and boron (B). The metal (M_{A1}) is not particularly limited as long as the metal (M_{A1}) has a function of absorbing EUV light and/or a phase shift function, can be processed by etching or the like (preferably, can be etched by dry etching with a chlorine (Cl)-based gas and/or a fluorine (F)-based gas), and has a high etching selective ratio to the multilayer reflective film 2 (the protective film 3 when the protective film 3 is present). As the metal (M_{A1}) having such a function, at least one metal selected from palladium (Pd), silver (Ag), platinum (Pt), gold (Au), iridium (Ir), tungsten (W), chromium (Cr), cobalt (Co), manganese (Mn), tin (Sn), tantalum (Ta), vanadium (V), nickel (Ni), hafnium (Hf), iron (Fe), copper (Cu), tellurium (Te), zinc (Zn), magnesium (Mg), germanium (Ge), aluminum (Al), rhodium (Rh), ruthenium (Ru), molybdenum (Mo), niobium (Nb), titanium (Ti), zirconium (Zr), yttrium (Y), and silicon (Si), an alloy containing two or more metals selected therefrom, or a compound thereof can be preferably used. The compound may contain the metal or alloy and oxygen (O), nitrogen (N), and/or carbon (C).

A material of the first absorption layer 42 preferably contains boron (B) and at least one metal (M_{A1}) selected from tantalum (Ta), chromium (Cr), platinum (Pt), ruthenium (Ru), and gold (Au). The metal (M_{A1}) contained in the material of the first absorption layer 42 can be a metal simple substance or an alloy containing two or more metals. The first absorption layer 42 may contain N, O, and/or H in addition to boron (B) and the metal (M_{A1}). The material of the first absorption layer 42 can be preferably at least one selected from TaB, TaBN, TaBNO, PtRuB, PtRuBN, AuB, AuBN, AuRuB, AuBN, AuCrB, AuCrBN, AuTaB, and AuTaBN. The metal (M_{A1}) contained in the first absorption layer 42 is the above-described element, whereby the absorber film 4 having predetermined optical characteristics with respect to EUV light that is exposure light can be obtained.

In the reflective mask blank 100 of the present embodiment, the first absorption layer 42 preferably contains tantalum (Ta). By inclusion of tantalum (Ta) in the first absorption layer 42, it is possible to more reliably obtain the absorber film 4 that is easily etched.

When the absorber film 4 has a phase shift function, the material of the first absorption layer 42 can contain boron (B) and at least one metal (M_{A1}) selected from platinum (Pt), ruthenium (Ru), and gold (Au). In order to increase an etching selective ratio to the first absorption layer 42, rhodium (Rh) may be contained as a material of the protective film 3. Since Rh has a low refractive index, when the film thickness of the protective film 3 changes, there arises a problem that an effective reflective surface Zeff of the multilayer reflective film 2 also easily fluctuates. Therefore, in order to suppress the fluctuation of the effective reflective surface Zeff of the multilayer reflective film 2, damage to the protective film 3 is preferably small. Note that, in the present specification, “damage to the protective film 3” includes not only an adverse effect on a surface of the protective film 3 but also unintentional etching and thinning of the protective film 3. By using the absorber film 4 of the present embodiment, it is possible to reduce damage to the multilayer reflective film 2 and/or the protective film 3 when an etching mask pattern 6a is removed by etching, and it is possible to suppress fluctuation of the effective reflective surface Zeff of the multilayer reflective film 2. Therefore, when the absorber film 4 has a phase shift function, the reflective mask blank 100 of the present embodiment can be preferably applied.

A content ratio of the metal (M_{A1}) in the first absorption layer 42 is preferably 60 to 98 atomic %, and more preferably 70 to 95 atomic %. Note that, when the metal (M_{A1}) is composed of a plurality of types of metals, the content ratio of the metal (M_{A1}) is a total content ratio of all the metals (M_{A1}). When the content ratio of the metal (M_{A1}) in the first absorption layer 42 is within the predetermined range, the absorber film 4 having a high absorption coefficient or the absorber film 4 having a preferable phase shift function can be obtained.

The first absorption layer 42 contains boron (B). By inclusion of boron (B) in the first absorption layer 42, a crystalline state of the first absorption layer 42 can be made amorphous. The crystalline state of the first absorption layer 42 is amorphous, whereby a surface of the absorber film 4 can be made smooth and flat. When the surface of the absorber film 4 is not smooth or flat, the absorber pattern 4a may have a large edge roughness and a poor pattern dimensional accuracy. The absorber film 4 has a surface roughness of preferably 0.5 nm or less, more preferably 0.4 nm or less, still more preferably 0.3 nm or less in terms of root mean square roughness (Rms).

In order to ensure that the crystalline state of the first absorption layer 42 is amorphous, a ratio between a content ratio of boron (B) and a content ratio of the metal (M_{A1}) (content ratio of boron (B)/content ratio of metal (M_{A1})) in the first absorption layer 42 is preferably 0.03 to 0.43, and more preferably 0.05 to 0.33.

The material of the first absorption layer 42 can contain boron (B), the metal (M_{A1}), and at least one selected from nitrogen (N), oxygen (O), and hydrogen (H). When the first absorption layer 42 contains nitrogen (N), a content ratio of nitrogen (N) is preferably 2 to 50 atomic %, and more preferably 5 to 35 atomic %. When the first absorption layer 42 contains oxygen (O), a content ratio of oxygen (O) is preferably 5 to 50 atomic %, and more preferably 15 to 40 atomic %. When the first absorption layer 42 contains hydrogen (H), a content ratio of hydrogen (H) is preferably 0.5 to 20 atomic %, and more preferably 1 to 10 atomic %.

The first absorption layer 42 can be made of a film having one type of composition. In addition, the first absorption layer 42 can be made of two or more films having different compositions. For example, the first absorption layer 42 can be a two-layer film including a lower layer and an upper layer.

The first absorption layer 42 can be a film having a uniform composition. In addition, the first absorption layer 42 can be a composition gradient film in which a content ratio of an element contained in the first absorption layer 42 changes in a film thickness direction.

The film thickness of the first absorption layer 42 can be 15 nm or more and 30 nm or more in order to satisfy optical characteristics with respect to EUV light. In addition, the film thickness of the first absorption layer 42 can be 80 nm or less and 70 nm or less in order to reduce a so-called shadowing effect.

As illustrated in FIGS. 1 and 2, the absorber film 4 of the reflective mask blank 100 of the present embodiment includes the second absorption layer 44. The second absorption layer 44 is disposed between the first absorption layer 42 described above and the etching mask film 6 described later. The second absorption layer 44 is preferably disposed in contact with a surface of the first absorption layer 42, and the etching mask film 6 is preferably disposed in contact with a surface of the second absorption layer 44.

In the present embodiment, the film thickness of the second absorption layer 44 can be 0.5 nm or more, or 1 nm or more. The film thickness of the second absorption layer 44 can be 20 nm or less, 10 nm or less, or 5 nm or less. When the film thickness of the second absorption layer 44 is within the predetermined range, it is possible to more reliably reduce diffusion of boron (B) contained in the absorber film 4 (particularly, the first absorption layer 42) into the etching mask film 6.

A material of the second absorption layer 44 contains a metal (M_{A2}). Similarly to the metal (M_{A1}) of the first absorption layer 42, the metal (M_{A2}) is not particularly limited as long as the metal (M_{A2}) has a function of absorbing EUV light and/or a phase shift function, can be processed by etching or the like (preferably, can be etched by dry etching with a chlorine (Cl)-based gas and/or a fluorine (F)-based gas), and has a high etching selective ratio to the multilayer reflective film 2 (the protective film 3 when the protective film 3 is present). As the metal (M_{A2}) having such a function, at least one metal selected from palladium (Pd), silver (Ag), platinum (Pt), gold (Au), iridium (Ir), tungsten (W), chromium (Cr), cobalt (Co), manganese (Mn), tin (Sn), tantalum (Ta), vanadium (V), nickel (Ni), hafnium (Hf), iron (Fe), copper (Cu), tellurium (Te), zinc (Zn), magnesium (Mg), germanium (Ge), aluminum (Al), rhodium (Rh), ruthenium (Ru), molybdenum (Mo), niobium (Nb), titanium (Ti), zirconium (Zr), yttrium (Y), and silicon (Si), an alloy containing two or more metals selected therefrom, or a compound thereof can be preferably used. When the material of the second absorption layer 44 contains a compound, the compound may contain the metal or alloy and oxygen (O), nitrogen (N), carbon (C), and/or boron (B).

In the present embodiment, similarly to the metal (M_{A1}) contained in the first absorption layer 42, the second absorption layer 44 preferably contains at least one metal (M_{A2}) selected from tantalum (Ta), chromium (Cr), platinum (Pt), ruthenium (Ru), and gold (Au). By inclusion of the above-described element in the second absorption layer 44, the absorber film 4 having predetermined optical characteristics with respect to EUV light that is exposure light can be obtained.

In the reflective mask blank 100 of the present embodiment, the second absorption layer 44 preferably contains tantalum (Ta) as the metal (M_{A2}) similarly to the metal (M_{A1}) of the first absorption layer 42. By inclusion of tantalum (Ta) in the second absorption layer 44, it is possible to more reliably obtain the absorber film 4 that is easily dry-etched.

When the absorber film 4 has a phase shift function, the material of the second absorption layer 44 can contain at least one metal (M_{A2}) selected from platinum (Pt), ruthenium (Ru), and gold (Au) similarly to the metal (M_{A1}) of the first absorption layer 42.

The metal (M_{A2}) contained in the material of the second absorption layer 44 is preferably the same element as the metal (M_{A1}) contained in the material of the first absorption layer 42. As a result, since the first absorption layer 42 and the second absorption layer 44 can be films having similar properties, productivity at the time of film formation is improved, and adhesion between the first absorption layer 42 and the second absorption layer 44 can be improved.

A content ratio of the metal (M_{A2}) in the second absorption layer 44 is preferably 40 to 100 atomic %, and more preferably 50 to 95 atomic %. Note that, when the metal (M_{A2}) is composed of a plurality of types of metals, the content ratio of the metal (M_{A2}) is a total content ratio of all the metals (M_{A2}). When the content ratio of the metal (M_{A2}) in the second absorption layer 44 is within the predetermined range, the absorber film 4 having a high absorption coefficient or the absorber film 4 having a preferable phase shift function can be obtained.

The material of the second absorption layer 44 can contain the metal (M_{A2}) and at least one selected from nitrogen (N), oxygen (O), and hydrogen (H). When the second absorption layer 44 contains nitrogen (N), a content ratio of nitrogen (N) is preferably 2 to 40 atomic %, and more preferably 5 to 30 atomic %. When the second absorption layer 44 contains oxygen (O), a content ratio of oxygen (O) is preferably 5 to 60 atomic %, and more preferably 15 to 50 atomic %. When the second absorption layer 44 contains hydrogen (H), a content ratio of hydrogen (H) is preferably 0.5 to 20 atomic %, and more preferably 1 to 10 atomic %.

The second absorption layer 44 can contain boron (B). In addition, a content ratio of boron (B) in the second absorption layer 44 is lower than a content ratio of boron (B) in the first absorption layer 42. Boron (B) is preferably not intentionally added at the time of forming the second absorption layer 44. Even when boron (B) is not intentionally added to the second absorption layer 44, the second absorption layer 44 contains boron (B) due to diffusion of boron (B) contained in the first absorption layer 42 into the second absorption layer 44. In the reflective mask blank 100 of the present embodiment, since the content ratio of boron (B) contained in the first absorption layer 42 and the second absorption layer 44 of the absorber film 4 has a predetermined distribution (content ratio profile) described later, diffusion of boron (B) contained in the absorber film 4 (particularly, the first absorption layer 42) into the etching mask film 6 can be reduced.

The second absorption layer 44 can be a film having a uniform composition. In addition, the second absorption layer 44 can be a composition gradient film in which a content ratio of an element contained in the second absorption layer 44 changes in a film thickness direction.

The absorber film 4 of the present embodiment can further include a film other than the first absorption layer 42 and the second absorption layer 44. For example, as illustrated in FIG. 2, the absorber film 4 of the present embodiment can include the buffer layer 46. The buffer layer 46 can be disposed between the first absorption layer 42 and the multilayer reflective film 2 or between the first absorption layer 42 and the protective film 3. By inclusion of the buffer layer 46 in the absorber film 4 of the present embodiment, damage to the multilayer reflective film 2 and/or the protective film 3 can be suppressed when the absorber film 4 is etched to form the absorber pattern 4a in the process of manufacturing the reflective mask 200.

As a material of the buffer layer 46, a similar material to that of the etching mask film 6 described later can be used. As the material of the buffer layer 46, a material containing chromium (Cr) or a chromium compound can be used. Examples of the chromium compound include a material containing Cr and at least one element selected from N, O, C, and H. The buffer layer 46 more preferably contains CrN, CrO, CrC, CrON, CrOC, CrCN, or CrOCN. In addition, as the material of the buffer layer 46, tantalum (Ta) or a tantalum compound can be used. Specifically, the material of the buffer layer 46 can contain TaN, TaO, TaON, TaBN, TaBO, or TaBON. Note that the material of the buffer layer 46 can contain boron (B). Note that the material of the buffer layer 46 does not have to contain boron (B).

The buffer layer 46 can be a film having a uniform composition. In addition, the buffer layer 46 can be a composition gradient film in which a content ratio of an element contained in the buffer layer 46 changes in a film thickness direction.

The film thickness of the buffer layer 46 is preferably 1.5 nm or more and 25 nm or less, and more preferably 2.5 nm or more and 15 nm or less. When the film thickness of the buffer layer 46 is within this range, it is possible to more reliably suppress damage to the multilayer reflective film 2 and/or the protective film 3 when the absorber film 4 is etched to form the absorber pattern 4a in the process of manufacturing the reflective mask 200.

In addition, by forming the absorber film 4 of the present embodiment into a multilayer film, functions of the absorber film 4 can be divided. For example, a lower layer of the first absorption layer 42 may have a function of absorbing EUV light and/or a phase shift function, and an upper layer of the first absorption layer 42 and the second absorption layer 44 may be antireflection films at the time of mask pattern defect inspection using light. This improves inspection sensitivity at the time of mask pattern defect inspection using light. In addition, when a film that contains oxygen (O), nitrogen (N), and the like and improves oxidation resistance is used as the second absorption layer 44, temporal stability of the reflective mask is improved. As described above, by forming the absorber film 4 into a multilayer film, various functions can be added to the absorber film 4. When the absorber film 4 is the absorber film 4 having a phase shift function, by forming the absorber film 4 into a multilayer film, a range of adjustment on an optical surface can be increased, and therefore a desired reflectance can be easily obtained.

The absorber film 4 including the first absorption layer 42 and the second absorption layer 44 can be formed by a magnetron sputtering method such as a DC sputtering method or an RF sputtering method. For example, the absorber film 4 such as a tantalum compound can be formed by a reactive sputtering method using a target containing, for example, tantalum and boron and using an argon gas containing oxygen or nitrogen.

### <<Etching Mask Film 6>>

As illustrated in FIGS. 1 and 2, the reflective mask blank 100 of the present embodiment includes the etching mask film 6 disposed in contact with the second absorption layer 44 of the absorber film 4. The etching mask film 6 contains a metal (M).

As a material of the etching mask film 6 containing the metal (M), a material having a high etching selective ratio (etching rate of absorber film 4/etching rate of etching mask film 6) of the absorber film 4 to the etching mask film 6 is preferably used. The etching selective ratio of the absorber film 4 to the etching mask film 6 is preferably 1.5 or more, and more preferably 3 or more.

In the reflective mask blank 100 of the present embodiment, the metal (M) of the etching mask film 6 preferably contains chromium (Cr). As the material of the etching mask film 6, a material containing chromium or a chromium compound can be used. When the material of the etching mask film 6 is chromium or a chromium compound, the etching mask film 6 can be dry-etched with a mixed gas of a chlorine-based gas and an oxygen gas, but has high resistance to dry etching with a fluorine-based gas. Therefore, when the material of the etching mask film 6 is chromium or a chromium compound and the material of the absorber film 4 contains tantalum (Ta), the etching mask film 6 can obtain a high etching selective ratio to the absorber film 4.

When the metal (M) of the etching mask film 6 is chromium (Cr), examples of the chromium compound include a material containing Cr and at least one element selected from N, O, C, and H. The etching mask film 6 more preferably contains CrN, CrO, CrC, CrON, CrOC, CrCN, or CrOCN.

When the metal (M) of the etching mask film 6 is chromium (Cr), a content ratio of chromium (Cr) in the etching mask film 6 is preferably 35 to 95 atomic %, and more preferably 50 to 90 atomic %. When the content ratio of the metal (M) in the etching mask film 6 is within the predetermined range, the etching mask film 6 having a high etching selective ratio to the absorber film 4 can be obtained.

The material of the etching mask film 6 can contain chromium (Cr) and at least one selected from nitrogen (N), oxygen (O), and carbon (C). When the etching mask film 6 contains nitrogen (N), a content ratio of nitrogen (N) is preferably 4 to 35 atomic %, and more preferably 8 to 25 atomic %. When the etching mask film 6 contains oxygen (O), a content ratio of oxygen (O) is preferably 5 to 50 atomic %, and more preferably 10 to 40 atomic %. When the etching mask film 6 contains carbon (C), a content ratio of carbon (C) is preferably 2 to 20 atomic %, and more preferably 4 to 10 atomic %.

As the material of the etching mask film 6, tantalum (Ta) or a tantalum compound can be used. In this case, the metal (M) of the etching mask film 6 is tantalum (Ta). Examples of the tantalum compound include a material containing Ta and at least one element selected from N, O, B, and H. The etching mask film 6 can contain TaN, TaO, TaON, TaBN, TaBO, or TaBON.

As the material of the etching mask film 6, silicon (Si) or a silicon compound can be used. In this case, the metal (M) of the etching mask film 6 is silicon (Si). Examples of the silicon compound include a material containing Si and at least one element selected from N, O, C, and H, a metallic silicon containing a metal in silicon or a silicon compound (metal silicide), a metal silicon compound (metal silicide compound), and the like. Examples of the metal silicon compound include a material containing a metal, Si, and at least one element selected from N, O, C, and H.

The film thickness of the etching mask film 6 is preferably 3 nm or more in order to accurately form a pattern on the absorber film 4. In addition, the film thickness of the etching mask film 6 is preferably 15 nm or less in order to reduce the film thickness of the resist film 11.

The etching mask film 6 can contain boron (B). Note that, when the etching mask film 6 is formed, it is preferable to form the etching mask film 6 under a condition that boron (B) is not intentionally contained in the etching mask film 6. Even in a case where the etching mask film 6 is formed under a condition that boron (B) is not intentionally contained in the etching mask film 6, there is a possibility that boron (B) is diffused into the etching mask film 6 from the second absorption layer 44 or from the first absorption layer 42 via the second absorption layer 44. That is, boron (B) of the absorber film 4 may diffuse into the etching mask film 6 formed in contact with a surface of the absorber film 4 (second absorption layer 44). The present inventors have found that by inclusion of boron (B) in the etching mask film 6, a phenomenon that an etching rate of the etching mask film 6 decreases occurs. When the etching rate of the etching mask film 6 decreases, the time for etching and removing the etching mask pattern 6a becomes long as described above in the process of manufacturing the reflective mask 200. This causes a problem that the multilayer reflective film 2 and/or the protective film 3 is damaged when the etching mask pattern 6a is removed by etching. As a result, a reflectance of the multilayer reflective film 2 with respect to EUV light decreases, and there arises a problem that performance of the reflective mask 200 is deteriorated. Therefore, a content ratio of boron (B) in the etching mask film 6 is preferably low. At least in the reflective mask blank 100 of the present embodiment, the content ratio of boron (B) in the etching mask film 6 is smaller than the content ratio of boron (B) in the second absorption layer 44. In addition, the etching mask film 6 particularly preferably contains no boron (B).

The etching mask film 6 can be a film having a uniform composition. In addition, the etching mask film 6 can be a composition gradient film in which a content ratio of an element contained in the etching mask film 6 changes in a film thickness direction.

The etching mask film 6 can be made of a single layer film and can be made of a plurality of films. When the etching mask film 6 is made of a plurality of films, the etching mask film 6 can further include a layer containing tantalum (Ta) and/or a layer containing silicon (Si) in addition to the above-described chromium (Cr)-containing layer constituting the etching mask film 6. The layer containing tantalum (Ta) and/or the layer containing silicon (Si) can be formed on a surface of the etching mask film 6 opposite to a surface in contact with the absorber film 4. As a material of the layer containing silicon (Si), silicon dioxide (SiO₂) can be used.

### <<Content Ratio Profile>>

In the present specification, the “content ratio profile of boron (B)” and the “content ratio profile of the metal (M)” mean a content ratio distribution of boron (B) and a content ratio distribution of the metal (M), respectively, in a sputtering time (t) (unit: minute) when the content ratio of boron (B) and the content ratio of metal the (M) are measured while the reflective mask blank 100 including the etching mask film 6, the second absorption layer 44, and the first absorption layer 42 is sputtered from a surface of the etching mask film 6 to at least a part of the first absorption layer 42 in a film thickness direction. As a sputtering gas for sputtering, for example, argon (Ar) can be used. The sputtering time t can be considered to correspond to a depth in the film thickness direction.

Note that the metal (M) contained in the etching mask film 6 diffuses into the second absorption layer 44 and the first absorption layer 42. Therefore, the second absorption layer 44 and the first absorption layer 42 also contain the metal (M). Similarly, boron (B) contained in the first absorption layer 42 diffuses into the second absorption layer 44 and the etching mask film 6. Therefore, the second absorption layer 44 and the etching mask film 6 also contain boron (B).

A content ratio of boron (B) and a content ratio of the metal (M) can be measured using X-ray photoelectron spectroscopy (XPS method). By measuring a content ratio of each of components (elements) corresponding to a sputtering time (t) when sputtering is performed in a film thickness direction from a surface of the etching mask film 6 to at least a part of the first absorption layer 42 by the XPS method, distributions (content ratio profiles) of the content ratio of boron (B) and the content ratio of the metal (M) can be obtained.

The present inventors have found that, when the distribution of the content ratio of boron (B) contained in the etching mask film 6 and the absorber film 4 (the second absorption layer 44 and the first absorption layer 42) in the film thickness direction is a predetermined distribution (content ratio profile), a problem that an etching rate of the etching mask film 6 decreases in the process of manufacturing the reflective mask 200 can be avoided, and have completed the present invention.

FIG. 5 illustrates a schematic diagram of content ratio profiles of boron (B) and the metal (M). In FIG. 5, the content ratio profile of boron (B) is indicated by a symbol C_{B}, and the content ratio profile of the metal (M) is indicated by a symbol C_{M}. Note that, when the metal (M) is composed of a plurality of types of metals, C_{M} indicates a total content ratio of all the metals (M). In FIG. 5, the horizontal axis represents a sputtering time (t), and the vertical axis represents a content ratio (atomic %) of boron (B) or the metal (M). When sputtering is started from a surface of the reflective mask blank 100 (a surface of the etching mask film 6), the content ratio of the metal (M) decreases and the content ratio of boron (B) increases with a lapse of the sputtering time (t). A reason for such a content ratio distribution is that the metal (M) contained in the etching mask film 6 diffuses into the absorber film 4 (the second absorption layer 44 and the first absorption layer 42), and boron (B) contained in the absorber film 4 (the second absorption layer 44 and the first absorption layer 42) diffuses into the etching mask film 6. When such diffusion occurs, each of the content ratio profiles of the metal (M) and boron (B) can be approximated by an arbitrary S-shaped function. In the present specification, an S-shaped function that approximates the content ratio profile of the metal (M) is represented by S_{M}(t), and an S-shaped function that approximates the content ratio profile of boron (B) is represented by S_{B}(t).

Examples of an arbitrary S-shaped function for approximating the content ratio profiles of boron (B) and the metal (M) include a sigmoid function and a Gaussian function. Examples of the sigmoid function include a higher order function of a cubic function or more, an error function, an exponential function, and a sine function. The S-shaped function has one inflection point in a region for approximating the content ratio profiles of boron (B) and the metal (M).

FIG. 5 illustrates how the content ratio of the metal (M) decreases before and after a point where the sputtering time (t) is u_{M}. That is, when the sputtering time (t) satisfies t<u_{M}, an absolute value of a slope of the content ratio of the metal (M) increases as the sputtering time (t) increases, but the sputtering time (t) satisfies t>u_{M}, the absolute value of the slope of the content ratio of the metal (M) decreases as the sputtering time (t) increases. That is, a point S_{M}(u_{M}) where the sputtering time (t) satisfies t=u_{M} can be said to be an inflection point of the content ratio profile S_{M}(t) of the metal (M). Since diffusion of atoms occurs between the etching mask film 6 and the second absorption layer 44, it is not easy to clearly define an interface between the etching mask film 6 and the second absorption layer 44. On the other hand, it is reasonable to consider that the inflection point of S_{M}(t) where the sputtering time (t) satisfies t=u_{M} is the interface between the etching mask film 6 and the second absorption layer 44. Therefore, in a case of considering the content ratio profiles of boron (B) and the metal (M) in the present specification, a depth in the film thickness direction where the sputtering time (t) corresponds to t=u_{M} is defined as the interface between the etching mask film 6 and the second absorption layer 44. Therefore, the content ratio of boron (B) contained in the entire etching mask film 6 can be considered to be obtained by integrating the content ratio profile C_{B} (=S_{B}(t)) of boron (B) from a surface (t=0) of the etching mask film 6 to the interface (t=u_{M}) between the etching mask film 6 and the second absorption layer 44.

The content ratio profile of the metal (M) can be approximated using an S-shaped function (sigmoid function) of the following formula (4). In formula (4), A_{M}, g_{M}, and u_{M} represent constants obtained by fitting. A sputtering time t where a second derivative of formula (4) is zero corresponds to an inflection point. Therefore, t=u_{M}, which is the inflection point, can be obtained by obtaining the sputtering time t where the second derivative of formula (4) is zero.

$$\begin{matrix}[ Mathematical Formula 2 ] & \\ {S}_{M} ( t ) = \frac{{A}_{M}}{1 + exp ( - {g}_{M} ( t - {u}_{M} ) )} & ( 4 )\end{matrix}$$

The present inventors have found that, when an integral value obtained by integrating the content ratio of boron (B) contained in the entire etching mask film 6 (the content ratio profile C_{B} (=S_{B}(t)) of boron (B)) from a surface (t=0) of the etching mask film 6 to an interface (t=u_{M}) between the etching mask film 6 and the second absorption layer 44 is a predetermined value 2.0 atomic %·min or less, it is possible to suppress the problem that the etching rate of the etching mask film 6 decreases in the process of manufacturing the reflective mask 200, and have completed the present invention.

That is, in the reflective mask blank 100 of the present embodiment, in the content ratio profiles S_{B}(t) of boron (B) and the metal (M) with respect to a sputtering time, obtained by sputtering at least a part of the etching mask film 6, the second absorption layer 44, and the first absorption layer 42 in the film thickness direction, the content ratio profile of boron (B) satisfies the following formula (1).

$$\begin{matrix}[ Mathematical Formula 3 ] & \\ {\int }_{- ∞}^{{u}_{M}} {S}_{B} ( t ) dt ≦ 2. ( atomic \% \cdot minute ) & ( 1 )\end{matrix}$$

In the above formula (1), t represents a sputtering time, u_{M} represents an inflection point when the content ratio profile of the metal (M) is approximated by an arbitrary S-shaped function, and S_{B}(t) represents an arbitrary S-shaped function approximating the content ratio profile of boron (B). In the above formula (1), a range of integral of t should be originally a range where t is 0 to u_{M}. However, as illustrated in FIG. 5, when the content ratio profile of boron (B) is approximated by the S-shaped function S_{B}(t), S_{B}(t) in a portion where t is smaller than 0 is extremely small and can be considered to be substantially zero. Therefore, in the above formula (1), even if the range of integral is set to a range where t is from minus infinity to u_{M}, it is substantially the same as integral in a range where t is from 0 to u_{M}. Rather, when the range of integral of the S-shaped function S_{B}(t) is set to the range where t is from minus infinity to u_{M}, calculation of integral of S_{B}(t) is easy. Therefore, in the present specification, in the above formula (1), the range of integral is set to the range where t is from minus infinity to u_{M}. FIG. 5 illustrates a portion corresponding to an integral value on the left side of formula (1).

Note that as the S-shaped function S_{B}(t) approximating the content ratio profile of boron (B), an S-shaped function (sigmoid function) of the following formula (2) can be used. In formula (2), A_{B}, g_{B}, and u_{B} represent constants obtained by fitting.

$$\begin{matrix}[ Mathematical Formula 4 ] & \\ {S}_{B} ( t ) = \frac{{A}_{B}}{1 + exp ( - {g}_{B} ( t - {u}_{B} ) )} & ( 2 )\end{matrix}$$

When the above formula (2) is put into the above formula (1), integral of the S-shaped function S_{B}(t) is as illustrated on the right side of the following formula (3). When the inflection point t=u_{M} of the S-shaped function S_{M}(t) approximating the content ratio profile of the metal (M) is found, the content ratio of boron (B) contained in the entire etching mask film 6 can be obtained from the following formula (3).

$$\begin{matrix}[ Mathematical Formula 5 ] & \\ {\int }_{- ∞}^{{u}_{M}} {S}_{B} ( t ) dt = \frac{{A}_{B}}{{g}_{B}} ln ( 1 + {e}^{{g}_{B} \cdot ( {u}_{M} - {u}_{B} )} ) & ( 3 )\end{matrix}$$

An integral value of S_{B}(t) in a range where t is from minus infinity to u_{M} indicated in formula (1) corresponds to the content ratio of boron (B) in the entire etching mask film 6. When the integral value indicated in formula (1) is 2.0 atomic %·minute or less, it is possible to reduce damage to the multilayer reflective film 2 and/or the protective film 3 when the etching mask pattern 6a is removed by etching. The integral value indicated on the left side of formula (1) is preferably 1.8 atomic %·minute or less, and more preferably 1.7 atomic %·minute or less. In addition, the integral value indicated on the left side of formula (1) can be more than 0 atomic %·minute, and can be 0.05 atomic %·minute or more.

### <Reflective Mask 200>

The present embodiment provides the reflective mask 200 having the absorber pattern 4a obtained by patterning the absorber film 4 of the above-described reflective mask blank 100.

As illustrated in FIG. 3E, the reflective mask 200 of the present embodiment has the absorber pattern 4a obtained by patterning the absorber film 4 disposed on the multilayer reflective film 2 or the protective film 3 of the above-described reflective mask blank 100.

FIGS. 3A to 3E are schematic views illustrating an example of a method for manufacturing the reflective mask 200. Using the above-described reflective mask blank 100 of the present embodiment, the reflective mask 200 of the present embodiment can be manufactured. Hereinafter, an example of the method for manufacturing the reflective mask 200 will be described.

First, the reflective mask blank 100 including the substrate 1, the multilayer reflective film 2, the absorber film 4, and the etching mask film 6 is prepared. The reflective mask blank 100 can include the protective film 3. Next, the resist film 11 is formed on the etching mask film 6 to obtain the reflective mask blank 100 with the resist film 11 (FIG. 3A). A pattern is drawn on the resist film 11 with an electron beam drawing device, and then the resulting product is subjected to a development and rinsing step to form a resist pattern 11a (FIG. 3B).

Next, the etching mask film 6 is dry-etched using the resist pattern 11a as a mask. As a result, a portion not covered with the resist pattern 11a in the etching mask film 6 is etched to form the etching mask pattern 6a (FIG. 3C). Note that the resist pattern 11a is removed with a resist peeling liquid.

Next, the absorber film 4 is dry-etched using the etching mask pattern 6a as a mask. As a result, a portion not covered with the etching mask pattern 6a in the absorber film 4 is etched to form the absorber pattern 4a (FIG. 3D).

As an etching gas for the absorber film 4, for example, a fluorine-based gas and/or a chlorine-based gas can be used. As the fluorine-based gas, CF₄, CHF₃, C₂F₆, C₃F₆, C₄F₆, C₄F₈, CH₂F₂, CH₃F, C₃F₈, SF₆, F₂, and the like can be used. As the chlorine-based gas, Cl₂, SiCl₄, CHCl₃, CCl₄, BCl₃, and the like can be used. In addition, a mixed gas containing a fluorine-based gas and/or a chlorine-based gas and O₂ at a predetermined ratio can be used. These etching gases can each further contain an inert gas such as He and/or Ar as necessary.

After the absorber pattern 4a is formed, the etching mask pattern 6a is removed by dry etching. In the reflective mask 200 of the present embodiment, it is possible to reduce diffusion of boron (B) contained in the absorber film 4 into the etching mask film 6. Therefore, when the etching mask pattern 6a is removed by etching, damage to the multilayer reflective film 2 and/or the protective film 3 can be reduced. After the etching mask pattern 6a is removed, the resulting product is subjected to a wet cleaning step using an acidic or alkaline aqueous solution to obtain the reflective mask 200 of the present embodiment (FIG. 3E).

The reflective mask 200 thus obtained has a structure in which the multilayer reflective film 2, the protective film 3, and the absorber pattern 4a are layered on the substrate 1.

A region (reflection region) where the multilayer reflective film 2 covered with the protective film 3 is exposed has a function of reflecting EUV light. A region where the multilayer reflective film 2 and the protective film 3 are covered with the absorber pattern 4a has a function of absorbing EUV light. When the etching mask pattern 6a is removed by etching, the reflective mask 200 of the present embodiment can reduce damage to the multilayer reflective film 2 and/or the protective film 3. Therefore, by using the reflective mask 200 of the present embodiment, it is possible to obtain a reflection region that maintains a high reflectance with respect to EUV light, and therefore a finer pattern can be transferred onto a transferred object in EUV lithography.

### <Method for Manufacturing Semiconductor Device>

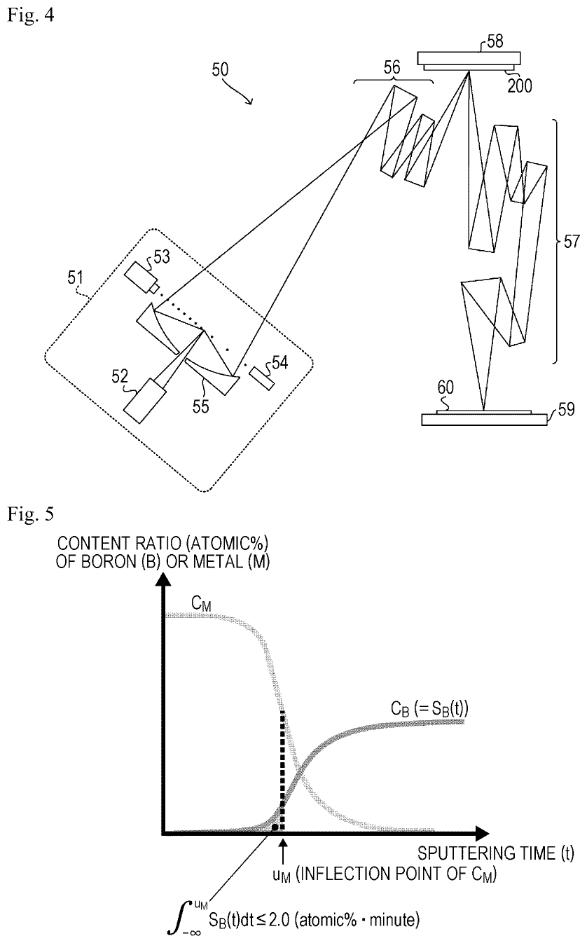

A method for manufacturing a semiconductor device of the present embodiment includes a step of performing a lithography process using an EUV exposure apparatus 50 using the above-described reflective mask 200 to form a transfer pattern on a transferred object. FIG. 4 illustrates a schematic diagram illustrating an example of the EUV exposure apparatus 50.

A transfer pattern can be formed on a semiconductor substrate 60 (transferred object) by lithography using the reflective mask 200 of the present embodiment. This transfer pattern has a shape obtained by transferring a pattern of the reflective mask 200. By forming a transfer pattern on the semiconductor substrate 60 with the reflective mask 200, a semiconductor device can be manufactured.

According to the present embodiment, in manufacture of the reflective mask 200, damage to the multilayer reflective film 2 and/or the protective film 3 can be reduced when the etching mask pattern 6a is removed by etching, and therefore the reflective mask 200 having a high reflectance with respect to EUV light can be obtained. Therefore, by using the reflective mask 200 of the present embodiment, it is possible to increase density and accuracy of a semiconductor device.

A method for transferring a pattern onto the semiconductor substrate 60 with resist using EUV light will be described with reference to FIG. 4.

FIG. 4 illustrates a schematic configuration of the EUV exposure apparatus 50 that is an apparatus for transferring a transfer pattern onto the resist film 11 formed on the semiconductor substrate 60. In the EUV exposure apparatus 50, an EUV light generation unit 51, an irradiation optical system 56, a reticle stage 58, a projection optical system 57, and a wafer stage 59 are precisely arranged along an optical path axis of EUV light. A container of the EUV exposure apparatus 50 is filled with a hydrogen gas.

The EUV light generation unit 51 includes a laser light source 52, a tin droplet generation unit 53, a catching unit 54, and a collector 55. When a tin droplet emitted from the tin droplet generation unit 53 is irradiated with a high-power carbon dioxide laser from the laser light source 52, tin in a droplet state is turned into plasma to generate EUV light. The generated EUV light is collected by the collector 55, passes through the irradiation optical system 56, and enters the reflective mask 200 set on the reticle stage 58. The EUV light generation unit 51 generates, for example, EUV light having a wavelength of 13.53 nm.

EUV light reflected by the reflective mask 200 is usually reduced to about ¼ of pattern image light by the projection optical system 57 and projected on the semiconductor substrate 60 (transferred substrate). As a result, a given circuit pattern is transferred onto the resist film on the semiconductor substrate 60. The resist film that has been subjected to exposure is developed, whereby a resist pattern can be formed on the semiconductor substrate 60. By etching the semiconductor substrate 60 using the resist pattern as a mask, an integrated circuit pattern can be formed on the semiconductor substrate 60. Through such steps and other necessary steps, a semiconductor device is manufactured.

### EXAMPLES

Hereinafter, Examples will be described. These Examples do not limit the present invention.

As each of Examples and Comparative Examples, the reflective mask blank 100 in which the multilayer reflective film 2, the protective film 3, the absorber film 4, and the etching mask film 6 were formed on a first main surface of the substrate 1 was prepared.

In the following Examples, a film thickness means a film thickness obtained from a film forming rate and a film forming time. That is, the film thickness means a film thickness immediately after each film is formed and before diffusion occurs between the plurality of films.

Table 1 presents compositions and film thicknesses of the absorber films 4 and the etching mask films 6 in Examples and Comparative Examples. The reflective mask blanks 100 in Examples and Comparative Examples were manufactured as follows.

A SiO₂—TiO₂-based glass substrate 1 that is a low thermal expansion glass substrate 1 having a 6025 size (approximately 152 mm×152 mm×6.35 mm) and having polished both main surfaces that are a first main surface and a second main surface was prepared as the substrate 1. The main surfaces were subjected to polishing including a rough polishing step, a precision polishing step, a local processing step, and a touch polishing step such that the main surfaces were flat and smooth.

The conductive back film 5 formed of a CrN film was formed on the second main surface (back surface) of the SiO₂—TiO₂-based glass substrate 1 by a magnetron sputtering (reactive sputtering) method. The conductive back film 5 was formed so as to have a film thickness of 70 nm in an argon (Ar) gas atmosphere using a TaB target.

Next, the multilayer reflective film 2 was formed on the main surface (first main surface) of the substrate 1 opposite to a side where the conductive back film 5 was formed. The multilayer reflective film 2 formed on the substrate 1 was a periodic multilayer reflective film containing Mo and Si in order to make the multilayer reflective film 2 suitable for EUV light having a wavelength of 13.5 nm. The multilayer reflective film 2 was formed using a Mo target and a Si target by alternately building up a Mo layer and a Si layer on the substrate 1 by an ion beam sputtering method in a krypton (Kr) gas atmosphere. First, a Si film was formed so as to have a film thickness of 4.2 nm, and then a Mo film was formed so as to have a film thickness of 2.8 nm. This stack was counted as one period, the stack of a Si film and a Mo film was built up for 40 periods in a similar manner, and finally, a Si film was formed so as to have a film thickness of 4.0 nm to form the multilayer reflective film 2.

Next, the protective film 3 formed of a RuRhCr film was formed on the multilayer reflective film 2. The protective film 3 was formed so as to have a film thickness of 3.5 nm by a DC magnetron sputtering method using a RuRhCr target (Ru:Rh:Cr=60 at %:30 at %:10 at %) in an Ar gas atmosphere.

Next, the predetermined absorber film 4 was formed on the protective film 3. Note that the film formation was performed in order of the buffer layer 46, the first absorption layer 42 (lower layer and upper layer), and the second absorption layer 44. As presented in Table 1, the absorber film 4 in each of Examples 1 to 4 and Comparative Example 1 includes the first absorption layer 42 (lower layer and upper layer) and the second absorption layer 44. As presented in Table 1, the absorber film 4 in each of Examples 5 and 6 includes the buffer layer 46, the first absorption layer 42, and the second absorption layer 44. As presented in Table 1, the absorber film 4 in each of Comparative Examples 2 and 3 includes the first absorption layer 42 but does not include the second absorption layer 44. As presented in Table 1, the absorber film 4 in Comparative Example 4 includes the buffer layer 46 and the first absorption layer 42. The film thickness of each layer of the absorber film 4 presented in Table 1 is a film thickness calculated from a film forming rate and a film forming time.

A CrN film having a film thickness presented in Table 1 was formed as the buffer layer 46 in each of Examples 5 and 6 and Comparative Example 4. The CrN film (buffer layer 46) was formed by a DC magnetron sputtering (reactive sputtering) method at power of 1500 W by introducing a mixed gas of an argon (Ar) gas with a gas flow rate of 10 sccm and a nitrogen (N₂) gas with a gas flow rate of 10 sccm using a Cr target.

A TaBN film having a film thickness presented in Table 1 was formed as a lower layer of the first absorption layer 42 in each of Examples 1 to 4 and Comparative Examples 1 to 3. The TaBN film was formed by a DC magnetron sputtering (reactive sputtering) method at power of 1500 W by introducing a mixed gas of an argon (Ar) gas with a gas flow rate of 9.9 sccm and a nitrogen (N₂) gas with a gas flow rate of 4.8 sccm using a TaB target.

A TaBO film having a film thickness presented in Table 1 was formed as an upper layer of the first absorption layer 42 in each of Examples 1 to 4 and Comparative Examples 1 to 3. The TaBO film was formed by a DC magnetron sputtering (reactive sputtering) method at power of 700 W by introducing a mixed gas of an argon (Ar) gas with a gas flow rate of 57 sccm and an oxygen (O₂) gas with a gas flow rate of 29 sccm using a TaB target.

A PtRuB film having a film thickness presented in Table 1 was formed as the first absorption layer 42 in each of Examples 5 and 6 and Comparative Example 4. The PtRuB film (first absorption layer 42) was formed by a DC magnetron sputtering method at power of 1200 W by introducing an argon (Ar) gas with a gas flow rate of 25 sccm using a PtRuB target.

A TaO film having a film thickness presented in Table 1 was formed as the second absorption layer 44 in each of Examples 1 to 4 and Comparative Example 1. The TaO film (second absorption layers 44) was formed by a DC magnetron sputtering (reactive sputtering) method at power of 700 W by introducing a mixed gas of an argon (Ar) gas with a gas flow rate of 50 sccm and an oxygen (O₂) gas with a gas flow rate of 20 sccm using a Ta target.

A Pt film having a film thickness presented in Table 1 was formed as the second absorption layer 44 in Example 5. The Pt film (second absorption layer 44) was formed by a DC magnetron sputtering (reactive sputtering) method at power of 1200 W by introducing an argon (Ar) gas with a gas flow rate of 25 sccm using a Pt target.

A Ru film having a film thickness presented in Table 1 was formed as the second absorption layer 44 in Example 6. The Ru film (second absorption layer 44) was formed by a DC magnetron sputtering (reactive sputtering) method at power of 1200 W by introducing an argon (Ar) gas with a gas flow rate of 25 sccm using a Ru target.

Next, the predetermined etching mask film 6 presented in Table 1 was formed on the absorber film 4. The film thickness of the etching mask film 6 presented in Table 1 is a film thickness calculated from a film forming rate and a film forming time.

A CrON film having a film thickness presented in Table 1 was formed as the etching mask film 6 in each of Examples 1 to 4 and Comparative Examples 1 to 3. The CrON film (etching mask film 6) was formed by a DC magnetron sputtering (reactive sputtering) method at power of 1300 W by introducing a mixed gas of an argon (Ar) gas with a gas flow rate of 20 sccm, an oxygen (O₂) gas with a gas flow rate of 10 sccm, and a nitrogen (N₂) gas with a gas flow rate of 10 sccm using a Cr target.

A CrN film and a SiO₂ film having film thicknesses presented in Table 1 were formed as the etching mask film 6 in each of Examples 5 and 6 and Comparative Example 4. The CrN film (lower layer of the etching mask film 6) was formed by a DC magnetron sputtering (reactive sputtering) method at power of 1500 W by introducing a mixed gas of an argon (Ar) gas with a gas flow rate of 10 sccm and a nitrogen (N₂) gas with a gas flow rate of 10 sccm using a Cr target. Next, the SiO₂ film (upper layer of the etching mask film 6) was formed by an RF sputtering method at power of 1500 W by introducing an argon (Ar) gas with a gas flow rate of 30 sccm using a SiO₂ target.

As described above, the reflective mask blanks 100 in Examples and Comparative Examples were manufactured.

### <Content Ratio Profiles of Chromium (Cr) and Boron (B)>

The metal (M) contained in the etching mask film 6 of the reflective mask blank 100 in each of Examples and Comparative Examples is chromium (Cr). Note that, in each of Examples 5 and 6, a SiO₂ film is formed as the upper layer of the etching mask film 6, but chromium (Cr) contained in the lower layer (CrN film) of the etching mask film 6 disposed in contact with the second absorption layer 44 can be selected as the metal (M). Therefore, content ratio profiles of chromium (Cr) and boron (B) of the etching mask film 6, the second absorption layer 44, and the first absorption layer 42 of the reflective mask blank 100 in each of Examples and Comparative Examples were measured. In the measurement of the content ratio profile, a composition corresponding to a sputtering time (t) (unit: min) was measured using X-ray photoelectron spectroscopy (XPS method) while sputtering was performed using Ar as a sputtering gas in a film thickness direction from the etching mask film 6. Sputtering was performed until the protective film 3 was reached.

Next, curve fitting for approximating measurement points of the content ratio profiles of chromium (Cr) and boron (B) of the reflective mask blank 100 in each of Examples and Comparative Examples obtained by the above-described measurement as an S-shaped function was performed.

The S-shaped function S_{B}(t) used for curve fitting of the measurement point of the content ratio profile of boron (B) is a sigmoid function of the following formula (2). Constants A_{B}, g_{B}, and u_{B} of the S-shaped function corresponding to the measurement results of each of Examples and Comparative Examples were obtained by curve fitting.

$$\begin{matrix}[ Mathematical Formula 6 ] & \\ {S}_{B} ( t ) = \frac{{A}_{B}}{1 + exp ( - {g}_{B} ( t - {u}_{B} ) )} & ( 2 )\end{matrix}$$

The S-shaped function used for curve fitting of the measurement point of the content ratio profile of chromium (Cr) is a sigmoid function of the following formula (4). Constants A_{M}, g_{M}, and u_{M} of the S-shaped function corresponding to the measurement results of each of Examples and Comparative Examples were obtained by curve fitting.

$$\begin{matrix}[ Mathematical Formula 7 ] & \\ {S}_{M} ( t ) = \frac{{A}_{M}}{1 + exp ( - {g}_{M} ( t - {u}_{M} ) )} & ( 4 )\end{matrix}$$

Next, t=u_{M}, which is an inflection point of formula (4), was obtained. The inflection point of formula (4) can be obtained by obtaining a sputtering time t where a second derivative of formula (4) is zero.

FIG. 5 schematically illustrates the content ratio profiles of chromium (Cr) and boron (B) obtained by the measurement. t=u_{M}, which is an inflection point, can be considered to be a time corresponding to an interface between the etching mask film 6 and the absorber film 4.

Next, an integral value was obtained by integrating the sigmoidal function of formula (2), which is an S-shaped function corresponding to the measurement result of the content ratio of boron (B) in each of Examples and Comparative Examples, in a range where t is from minus infinity to u_{M} (see the following formula (5)). Formula (5) is the same as the left side of formula (1) described above. Table 1 presents a calculation result of an integral value of this formula (5) (left side of formula (1)). The integral value of formula (5) (the left side of formula (1)) corresponds to a content ratio of boron (B) in the entire etching mask film 6.

$$\begin{matrix}[ Mathematical Formula 8 ] & \\ {\int }_{- ∞}^{{u}_{M}} {S}_{B} ( t ) dt & ( 5 )\end{matrix}$$

As is clear from Table 1, the integral value of formula (5) (the left side of formula (1)) in each of Examples 1 to 6 was 1.67 (Example 4) or less. On the other hand, the integral value of formula (5) (the left side of Formula (1)) in each of Comparative Examples 1 to 4 was 2.10 (Comparative Example 1) or more. The integral value of formula (5) (the left side of formula (1)) corresponds to a content ratio of boron (B) in the entire etching mask film 6. Therefore, in the predetermined reflective mask blank 100 of the present embodiment, it can be said that diffusion of boron (B) contained in the absorber film 4 into the etching mask film 6 can be reduced.

### <Repair Resistance Test>

A test for evaluating repair resistance of the protective film 3 was performed using the reflective mask blank 100 in each of Examples and Comparative Examples in order to evaluate whether the protective film 3 was damaged.

First, as illustrated in FIG. 3A, the resist film 11 was formed on the absorber film 4 of the reflective mask blank 100 in each of Examples and Comparative Examples. Then, a predetermined pattern was drawn (exposed) on this resist film 11, and further developed and rinsed to form the resist pattern 11a (FIG. 3B). Note that the shape of the resist pattern 11a was a square shape having a side of 5 mm, and was a shape in which the resist pattern 11a was not formed in this square region. Therefore, the protective film 3 in the square region is finally exposed by a subsequent step of etching the absorber film 4.

Next, the etching mask film 6 was dry-etched using the resist pattern 11a as a mask to form the etching mask pattern 6a (FIG. 3C). Specifically, in each of the samples of Examples 1 to 4 and Comparative Examples 1 to 3, the etching mask film 6 (CrON film) was dry-etched using a mixed gas of a Cl₂ gas and an O₂ gas. In each of the samples of Examples 5 and 6 and Comparative Example 4, the upper layer (SiO₂ film) of the etching mask film 6 was dry-etched using a mixed gas of a CF₄ gas and a He gas, and the lower layer (CrN film) of the etching mask film 6 was dry-etched using a mixed gas of a Cl₂ gas and an O₂ gas.

Next, the absorber film 4 was dry-etched using the etching mask pattern 6a as a mask to form the absorber pattern 4a (FIG. 3D). Specifically, in each of the samples in Examples 1 to 4 and Comparative Example 1, the second absorption layer 44 (TaO film) and the upper layer (TaBO film) of the first absorption layer 42 were dry-etched using a mixed gas of a CF₄ gas and a He gas, and the lower layer (TaBN film) of the first absorption layer 42 was dry-etched using a Cl₂ gas. In each of the samples in Comparative Examples 2 and 3, the upper layer (TaBO film) of the first absorption layer 42 was dry-etched using a mixed gas of a CF₄ gas and a He gas, and the lower layer (TaBN film) of the first absorption layer 42 was dry-etched using a Cl₂ gas. In each of the samples in Examples 5 and 6 and Comparative Example 4, the absorber film 4 (the second absorption layer 44 and the first absorption layer 42) was dry-etched using a mixed gas of a CF₄ gas and a He gas. At this time, the upper layer (SiO₂ film) of the etching mask pattern 6a was also removed at the same time.

Thereafter, the etching mask pattern 6a was removed by dry etching (FIG. 3E). Specifically, in each of the samples in Examples and Comparative Examples, the etching mask pattern 6a (CrON film) or the lower layer (CrN film) of the etching mask pattern 6a was dry-etched using a mixed gas of a Cl₂ gas and an O₂ gas to remove the etching mask pattern 6a. As a result, the protective film 3 was exposed as a square pattern having a side of 5 mm.

Next, a test for evaluating repair resistance of the protective film 3 exposed as described above was performed using a repair device. Specifically, a treatment of irradiating a surface of the protective film 3 with an electron beam while supplying a fluorine-based etching gas (XeF₂+H₂O) to a periphery of the protective film 3 was repeated. Test conditions are as follows.

### (Repair Resistance Test Conditions)

Acceleration voltage of electron beam: 1 kV
XeF₂ temperature: 0 °C.
H₂O temperature: −42 °C.
Electron beam irradiation time per unit pixel (1.5 nm×1.5 nm): 4.00×10⁻⁸ [s]
Definition of one loop: A process of repeatedly performing scanning with an electron beam in the horizontal direction at predetermined intervals in the vertical direction to finish scanning the entire area of 500 nm×500 nm is defined as one loop.

After the treatment of irradiating the surface of the protective film 3 with an electron beam was repeated, the surface of the protective film 3 was photographed by a scanning electron microscope (SEM). Then, the number of times of electron beam irradiation (the number of loops) until damage was observed by an SEM on the surface of the protective film 3 was measured. Table 2 presents the number of times of electron beam irradiation (the number of loops) in each of Examples and Comparative Examples. In Table 2, the number of times of electron beam irradiation (the number of loops) is indicated as a ratio when the number of loops in Comparative Example 1 is 1.0.

As can be seen from the results presented in Table 2, the number of loops of the protective film 3 in the repair resistance test in the case of using the reflective mask blank 100 in each of Examples 1 to 6 was larger than the number of loops of the protective film 3 of the reflective mask blank 100 in each of Comparative Examples 1 to 4. That is, it has been found that the protective film 3 of the reflective mask blank 100 in each of Examples 1 to 6 has high resistance to repair by electron beam irradiation using a fluorine-based etching gas (XeF₂+H₂O). This indicates that in the case of using the reflective mask blank 100 in each of Examples 1 to 6, damage to the protective film 3 when the etching mask pattern 6a was removed by etching could be reduced.

TABLE 1

| | | | Composition of | | |
|---|---|---|---|---|---|
| | Composition of | | second | | Value of left |
| | buffer layer | Composition of first absorption | absorption layer | Composition of etching | side of formula |
| | (film thickness) | layer (film thickness) | (film thickness) | mask film (film thickness) | (1) |
| Example 1 | — | TaBN (55 nm)/TaBO (2 nm) | TaO (2.5 nm) | CrON (6 nm) | 0.10 |
| Example 2 | — | TaBN (55 nm)/TaBO (2 nm) | TaO (2.0 nm) | CrON (6 nm) | 0.51 |
| Example 3 | — | TaBN (55 nm)/TaBO (2 nm) | TaO (1.5 nm) | CrON (6 nm) | 1.18 |
| Example 4 | — | TaBN (55 nm)/TaBO (2 nm) | TaO (1.0 nm) | CrON (6 nm) | 1.67 |
| Example 5 | CrN (4 nm) | PtRuB (30 nm) | Pt (2.0 nm) | CrN (16 nm)/SiO2 (5 nm) | 0.24 |
| Example 6 | CrN (4 nm) | PtRuB (30 nm) | Ru (2.0 nm) | CrN (16 nm)/SiO2 (5 nm) | 0.29 |
| Comparative | — | TaBN (55 nm)/TaBO (2 nm) | TaO (0.4 nm) | CrON (6 nm) | 2.10 |
| Example 1 | | | | | |
| Comparative | — | TaBN (57 nm)/TaBO (2 nm) | — | CrON (6 nm) | 2.28 |
| Example 2 | | | | | |
| Comparative | — | TaBN (55 nm)/TaBO (4 nm) | — | CrON (6 nm) | 2.18 |
| Example 3 | | | | | |
| Comparative | CrN (4 nm) | PtRuB (32 nm) | — | CrN (16 nm)/SiO2 (5 nm) | 2.23 |
| Example 4 | | | | | |

TABLE 2

| | Repair resistance (number of loops) |
|---|---|
| Example 1 | 3.2 |
| Example 2 | 3.1 |
| Example 3 | 2.4 |
| Example 4 | 1.4 |
| Example 5 | 2.1 |
| Example 6 | 1.9 |
| Comparative Example 1 | 1.0 |
| Comparative Example 2 | 0.8 |
| Comparative Example 3 | 0.9 |
| Comparative Example 4 | 0.7 |

### REFERENCE SIGNS LIST

1 Substrate
2 Multilayer reflective film
3 Protective film
4 Absorber film
4a Absorber pattern
5 Conductive back film
6 Etching mask film
6a Etching mask pattern
11 Resist film
11a Resist pattern
42 First absorption layer
42a First absorption layer pattern
44 Second absorption layer
44a Second absorption layer pattern
46 Buffer layer
50 EUV exposure apparatus
51 EUV light generation unit
52 Laser light source
53 Tin droplet generation unit
54 Catching unit
55 Collector
56 Irradiation optical system
57 Projection optical system
58 Reticle stage
59 Wafer stage
60 Semiconductor substrate
100 Reflective mask blank
200 Reflective mask

1. A reflective mask blank comprising:
a substrate;
a multilayer reflective film disposed on the substrate;
an absorber film disposed on the multilayer reflective film and comprising a first absorption layer and a second absorption layer; and
an etching mask film disposed in contact with the second absorption layer,
wherein:
the first absorption layer comprises boron (B),
a content ratio of boron (B) in the second absorption layer is smaller than a content ratio of boron (B) in the first absorption layer,
the etching mask film comprises a metal (M), and
in content ratio profiles of boron (B) and the metal (M) in the reflective mask blank including the etching mask film, the second absorption layer, and the first absorption layer with respect to a sputtering time, obtained by sputtering at least a part of the etching mask film, the second absorption layer, and the first absorption layer in a film thickness direction,
the content ratio profile of boron (B) satisfies the following formula (1):
$${\int }_{- ∞}^{{u}_{M}} {S}_{B} ( t ) dt ≦ 2. ( atomic \% \cdot minute ) \qquad ( 1 )$$
in which t represents a sputtering time,
S_{B}(t) represents an arbitrary S-shaped function approximating the content ratio profile of boron (B), and
uM represents an inflection point when the content ratio profile of the metal (M) is approximated by the arbitrary S-shaped function.

2. The reflective mask blank according to claim 1, wherein the second absorption layer has a film thickness of 0.5 nm or more and 20 nm or less.

3. The reflective mask blank according to claim 1, wherein the second absorption layer comprises at least one metal selected from tantalum (Ta), chromium (Cr), platinum (Pt), ruthenium (Ru), and gold (Au).

4. The reflective mask blank according to claim 1, wherein the first absorption layer comprises at least one metal selected from tantalum (Ta), chromium (Cr), platinum (Pt), ruthenium (Ru), and gold (Au).

5. The reflective mask blank according to claim 1, wherein the first absorption layer and the second absorption layer each comprise tantalum (Ta).

6. The reflective mask blank according to claim 1, wherein the metal (M) of the etching mask film comprises chromium (Cr).

7. The reflective mask blank according to claim 1, further comprising a protective film comprising at least one metal selected from ruthenium (Ru) and rhodium (Rh) between the multilayer reflective film and the absorber film.

8. A reflective mask comprising an absorber pattern obtained from the reflective mask blank according to claim 1,
wherein the absorber pattern is obtained by patterning the absorber film disposed on the multilayer reflective film of the reflective mask blank.

9. A method for manufacturing a reflective mask, the method comprising:
preparing a reflective mask blank comprising an absorber film; and
patterning the absorber film to form an absorber pattern,
wherein:
the reflective mask blank comprises:
a substrate;
a multilayer reflective film disposed on the substrate;
the absorber film disposed on the multilayer reflective film and comprising a first absorption layer and a second absorption layer; and
an etching mask film disposed in contact with the second absorption layer,
the first absorption layer comprises boron (B),
a content ratio of boron (B) in the second absorption layer is smaller than a content ratio of boron (B) in the first absorption layer,
the etching mask film comprises a metal (M), and
in content ratio profiles of boron (B) and the metal (M) in the reflective mask blank including the etching mask film, the second absorption layer, and the first absorption layer with respect to a sputtering time, obtained by sputtering at least a part of the etching mask film, the second absorption layer, and the first absorption layer in a film thickness direction,
the content ratio profile of boron (B) satisfies the following formula (1):
$${\int }_{- ∞}^{{u}_{M}} {S}_{B} ( t ) dt ≦ 2. ( atomic \% \cdot minute ) \qquad ( 1 )$$
in which t represents a sputtering time,
S_{B}(t) represents an arbitrary S-shaped function approximating the content ratio profile of boron (B), and
uM represents an inflection point when the content ratio profile of the metal (M) is approximated by the arbitrary S-shaped function.

10. The method for manufacturing a reflective mask according to claim 9, wherein the second absorption layer has a film thickness of 0.5 nm or more and 20 nm or less.

11. The method for manufacturing a reflective mask according to claim 9, wherein the second absorption layer comprises at least one metal selected from tantalum (Ta), chromium (Cr), platinum (Pt), ruthenium (Ru), and gold (Au).

12. The method for manufacturing a reflective mask according to claim 9, wherein the first absorption layer comprises at least one metal selected from tantalum (Ta), chromium (Cr), platinum (Pt), ruthenium (Ru), and gold (Au).

13. The method for manufacturing a reflective mask according to claim 9, wherein the first absorption layer and the second absorption layer each comprise tantalum (Ta).

14. The method for manufacturing a reflective mask according to claim 9, wherein the metal (M) of the etching mask film comprises chromium (Cr).

15. The method for manufacturing a reflective mask according to claim 9, wherein the reflective mask blank further comprises a protective film comprising at least one metal selected from ruthenium (Ru) and rhodium (Rh) between the multilayer reflective film and the absorber film.

16. (canceled)

17. The reflective mask blank according to claim 1, wherein the second absorption layer comprises oxygen (O) and has a film thickness of 0.5 nm or more and 10 nm or less.

18. The reflective mask blank according to claim 1, wherein the first absorption layer comprises a lower layer and an upper layer, and the upper layer comprises oxygen (O).
